(19) United States
(12) Patent Application Publication
(10) Pub. No.: US 2024/0074201 A1
(43) Pub. Date: Feb. 29, 2024

(54) Memory Circuitry And Method Used In Forming Memory Circuitry

(71) Applicant: Micron Technology, Inc., Boise, ID (US)

(72) Inventors: Matthew J. King, Boise, ID (US); Albert Fayrushin, Boise, ID (US); Sidhartha Gupta, Boise, ID (US); Jun Fujiki, Tokyo (JP); Masashi Yoshida, Kanagawa (JP); Yiping Wang, Boise, ID (US); Taehyun Kim, Boise, ID (US); Arun Kumar Dhayalan, Boise, ID (US)

(73) Assignee: Micron Technology, Inc., Boise, ID (US)

(21) Appl. No.: 17/893,436

(22) Filed: Aug. 23, 2022

(51) Int. Cl. H01L 27/1157; H01L 27/11524; H01L 27/11556; H01L 27/11582

(52) U.S. Cl. CPC H01L 27/1157; H01L 27/11524; H01L 27/11556; H01L 27/11582

(57) ABSTRACT

A method used in forming a memory array comprising strings of memory cells comprises forming a stack comprising vertically-alternating different-composition first tiers and second tiers. The stack comprises lower channel-material strings extending through the first tiers and the second tiers. Conductive masses are formed that comprise at least one of conductively-doped semiconductive material or conductive metal material. Individual of the conductive masses are atop and directly electrically coupled to individual of the lower channel-material strings. Upper channel-material strings of select-gate transistors are formed directly above the stack. Individual of the upper channel-material strings are directly above and directly electrically coupled to individual of the conductive masses. Other embodiments, including structure, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-5 are diagrammatic cross-sectional views of portions of a construction that will comprise an array of elevationally-extending strings of memory cells in accordance with an embodiment of the invention.

FIGS. 6-22 are diagrammatic sequential sectional and/or enlarged views of the construction of FIG. 1-5, or portions thereof or alternate and/or additional embodiments, in process in accordance with some embodiments of the invention.

### DETAILED DESCRIPTION OF EXAMPLE EMBODIMENTS

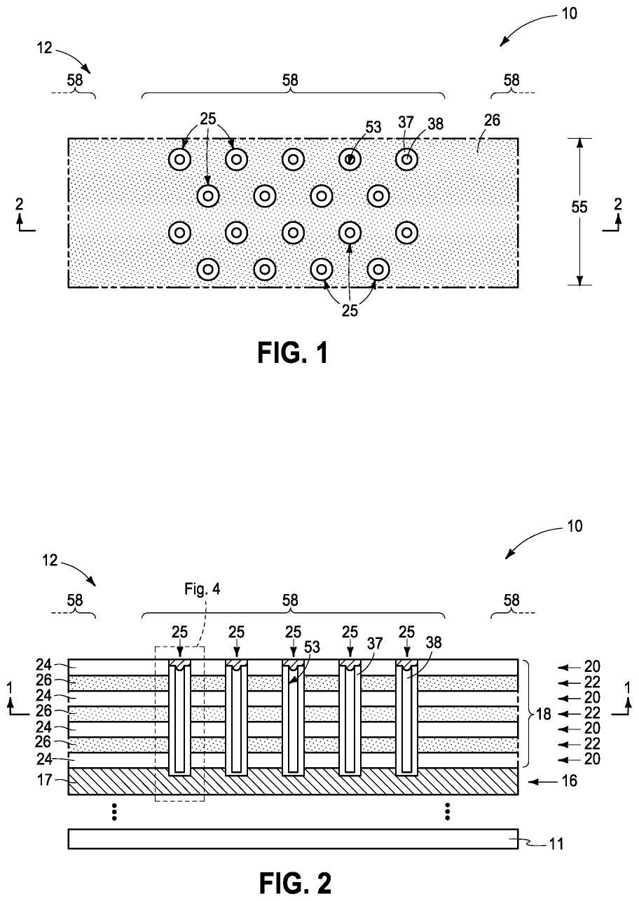

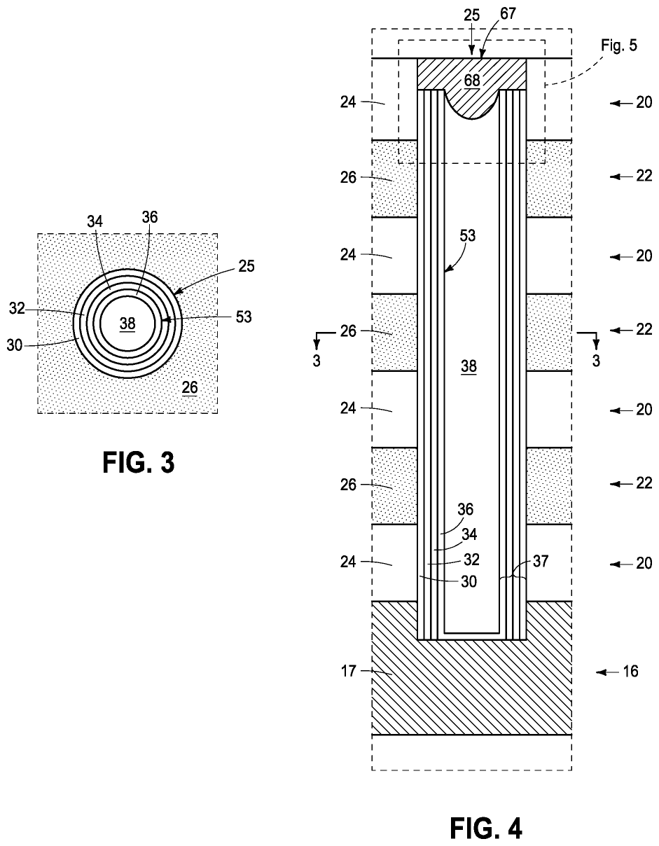

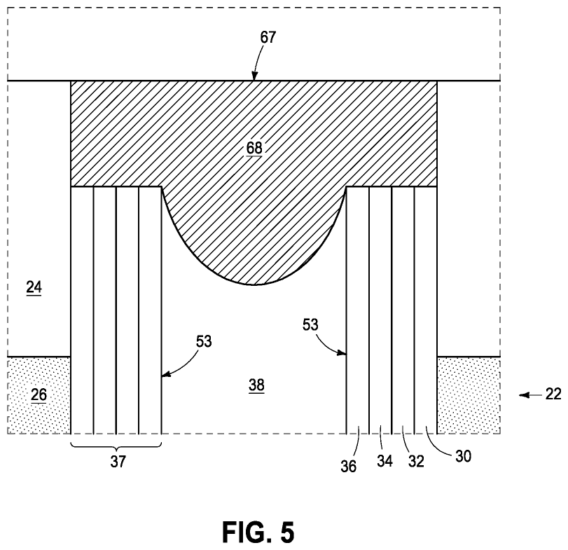

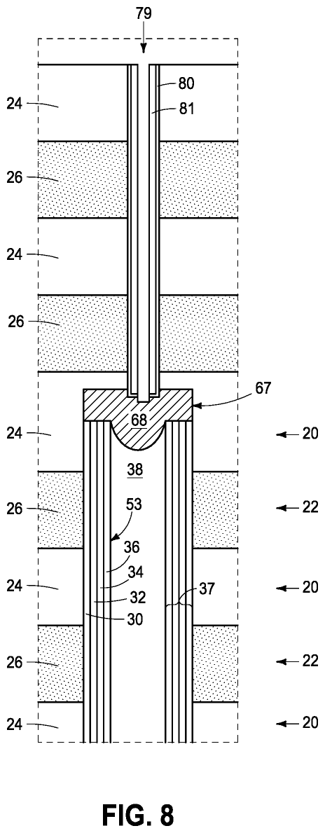

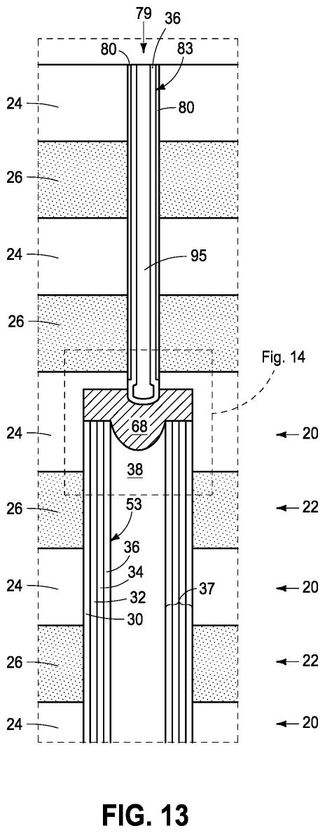

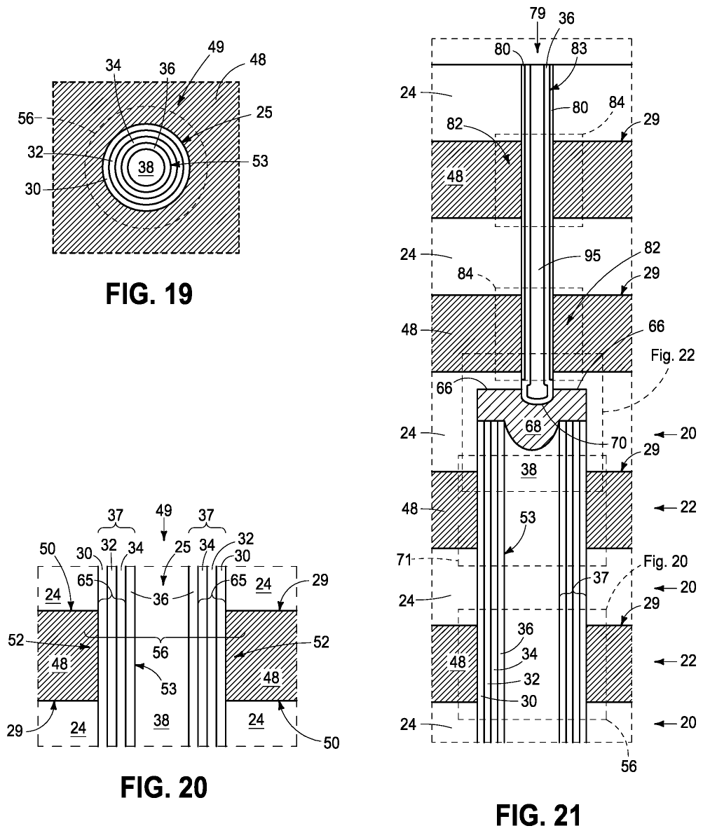

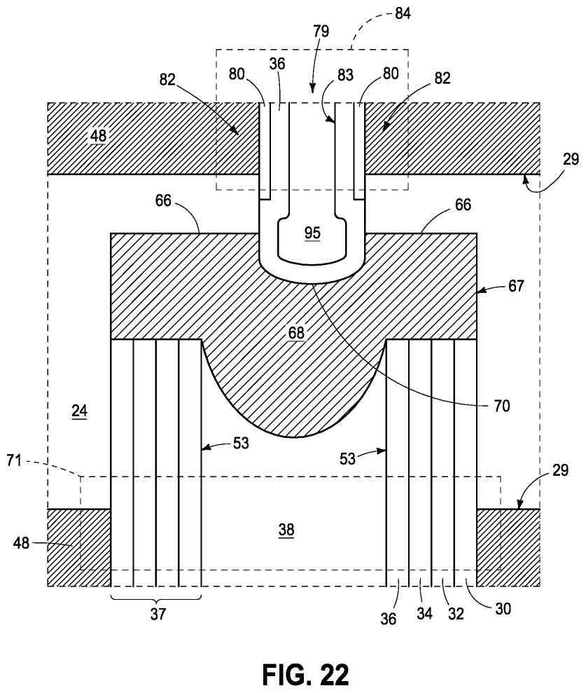

Embodiments of the invention encompass methods used in forming a memory array, for example an array of NAND or other memory cells that may have at least some peripheral control circuitry under the array (e.g., CMOS-under-array). Embodiments of the invention encompass so-called “gate-last” or “replacement-gate” processing, so-called “gate-first” processing, and other processing whether existing or future-developed independent of when transistor gates are formed. Embodiments of the invention also encompass integrated circuitry comprising a memory array comprising strings of memory cells (e.g., NAND architecture) independent of method of manufacture. First example method embodiments are described with reference to FIGS. 1-22.

FIGS. 1-5 show an example construction 10 having an array 12 in which elevationally-extending strings of transistors and/or memory cells will be formed. Such includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-6-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) is above substrate 11. Conductor tier 16 may comprise part of control circuitry (e.g., peripheral-under-array circuitry and/or a common source line or plate) used to control read and write access to the transistors and/or memory cells in array 12. A stack 18 comprising vertically-alternating insulative tiers 20 and conductive tiers 22 is directly above conductor tier 16. In some embodiments, conductive tiers 22 may be referred to as first tiers 22 and insulative tiers 20 may be referred to as second tiers 20. First tiers 22 may be conductive and second tiers 20 may be insulative, yet need not be so at this point of processing in conjunction with the hereby initially-described example method embodiment which is “gate-last” or “replacement-gate”. Example thickness for each of tiers 20 and 22 is 20 to 60 nanometers. The example uppermost tier 20 may be thicker/thickest compared to one or more other tiers 20 and/or 22. Example first tiers 22 comprise material 26 (e.g., silicon nitride) and example second tiers 20 comprise material 24 (e.g., silicon dioxide). Only a small number of tiers 20 and 22 is shown in FIGS. 1-4, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22 and/or above an uppermost of the conductive tiers 22. For example, one or more select gate tiers (not shown) may be between conductor tier 16 and the lowest conductive tier 22. Alternately or additionally, at least one of the depicted lowest conductive tiers 22 may be a select gate tier.

Channel openings 25 have been formed (e.g., by etching) through insulative tiers 20 and conductive tiers 22 to conductor tier 16. Channel openings 25 may taper radially-inward and/or radially-outward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest insulative tier 20. A reason for extending channel openings 25 at least to conductor material 17 of conductor tier 16 is to assure direct electrical coupling of channel material to conductor tier 16 without using alternative processing and structure to do so when such a connection is desired and/or to provide an anchoring effect to material that is within channel openings 25. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of four and five openings 25 per row and being arrayed in laterally-spaced memory-block regions 58 that will comprise laterally-spaced memory blocks 58 in a finished circuitry construction. In this document, “block” is generic to include “sub-block”. Memory-block regions 58 and resultant memory blocks 58 (not yet shown) may be considered as being longitudinally elongated and oriented, for example along a first direction 55. Any alternate existing or future-developed arrangement and construction may be used.

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

The FIGURES show one embodiment wherein charge-blocking material 30, storage material 32, and charge-passage material 34 have been formed in individual channel openings 25 elevationally along insulative tiers 20 and conductive tiers 22. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18 as shown.

Channel material 36 has also been formed in channel openings 25 elevationally along insulative tiers 20 and conductive tiers 22 and comprise individual lower channel-material strings 53 in one embodiment having memory-cell materials (e.g., 30, 32, and 34) there-along and with material 24 in insulative tiers 20 being horizontally-between immediately-adjacent lower channel-material strings 53. Materials 30, 32, 34, and 36 are collectively shown as and only designated as material 37 in some FIGURES due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 (lower channel-material string 53) is directly electrically coupled with conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled with conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown). Materials 30, 32, 34, and 36 are shown as having planar tops and which are coplanar, although alternate constructions may be used, for example whereby channel material 36 has its top higher than each of materials 30, 32, and 34.

Conductive masses 67 have been formed and that are individually atop and directly electrically coupled to individual lower channel-material strings 53. In this document, a “conductive mass” is a quantity or aggregate of matter that is intrinsically overall electrically conductive there-though, for example even if containing some region that is locally not electrically conductive. In one embodiment, conductive masses 67 comprise at least one of conductively-doped semiconductive material 68 or conductive metal material 68. In such embodiment, only one or both of the at least one of the conductively-doped semiconductive material and the conductive metal material may constitute conductive material 68. In one embodiment, the at least one of the conductively-doped semiconductive material and the conductive metal material comprises conductively-doped semiconductive material, in one such embodiment comprises conductively n-type doped semiconductive material, and in one such latter embodiment comprises conductively n-type doped polysilicon. In one embodiment, the at least one of the conductively-doped semiconductive material and the conductive metal material comprises conductive metal material (e.g., Ti, TiN, W, and/or a metal silicide).

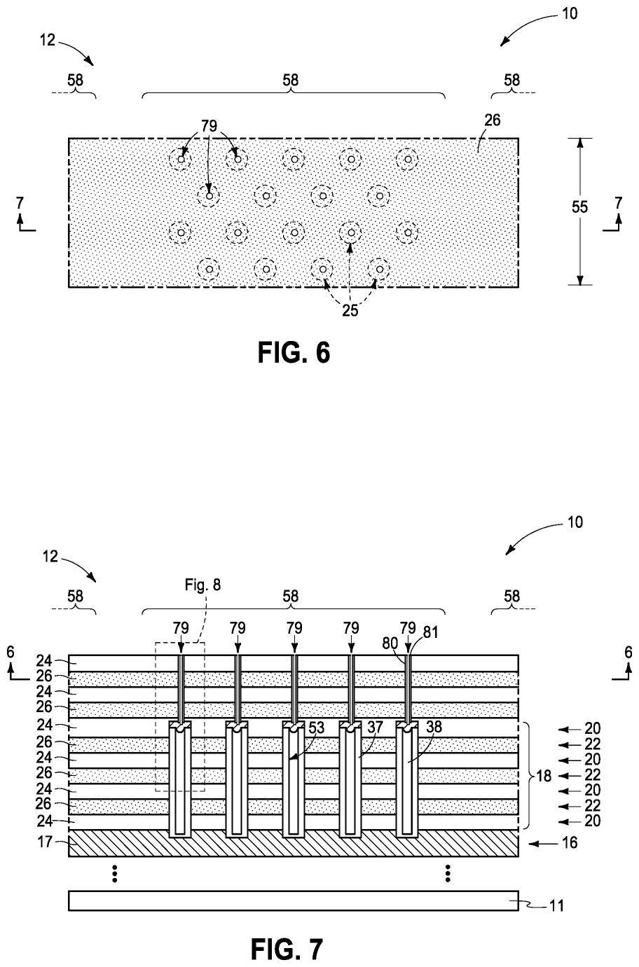

Referring to FIGS. 6-8, and in one embodiment, additional alternating first and second tiers 20 and 22 have been formed above stack 18 for fabrication of select-gate transistors (e.g., select gate drains). Upper channel openings 79 have been formed that are directly above (at least partially) conductive masses 67, and which are ideally smaller than channel openings 25. Individual upper channel openings 79 may be aligned differently with respect to individual lower channel openings 25 and, regardless, may not be centered thereover. In one embodiment, upper channel openings 79 extend downwardly into conductive material 68 of conductive masses 67. Upper channel openings 79 have been lined with a gate insulator 80 (e.g., silicon dioxide) and sacrificial material 81 (e.g., polysilicon). Thereafter, such sacrificial material 81 and gate insulator 80 have been punch-etched to expose conductive material 68 of conductive masses 67 and which may extend upper channel openings deeper into conductive material 68 as shown.

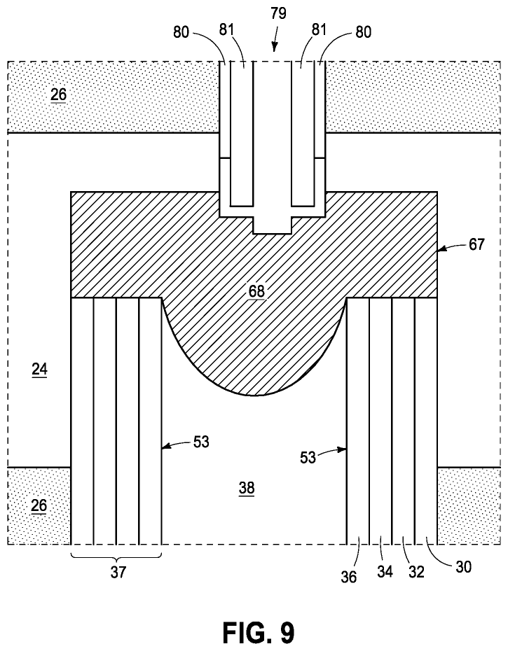

FIG. 9 shows example subsequent etch-back of gate insulator 80.

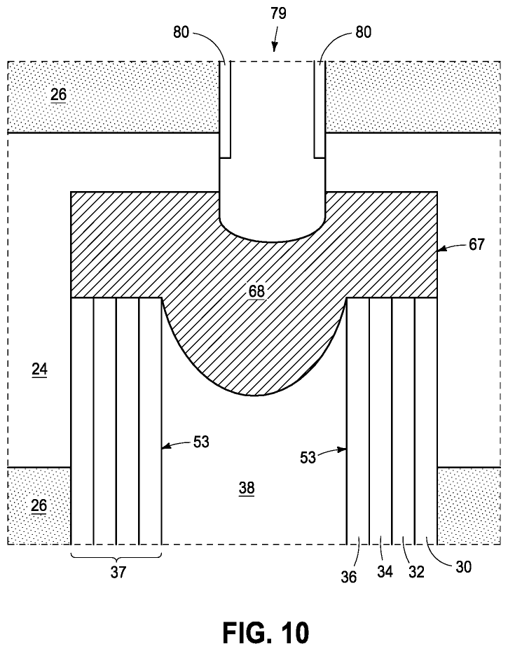

FIG. 10 shows example subsequent removing (e.g., by isotropic etching) of sacrificial material 81 (not shown). For example, if such is polysilicon, tetramethylammonium hydroxide (TMAH) may be used as an isotropic etching chemistry in a short, timed etch, with the TMAH also etching slightly into conductive material 68 of conductive masses 67 when conductive material 68 is conductively-doped polysilicon.

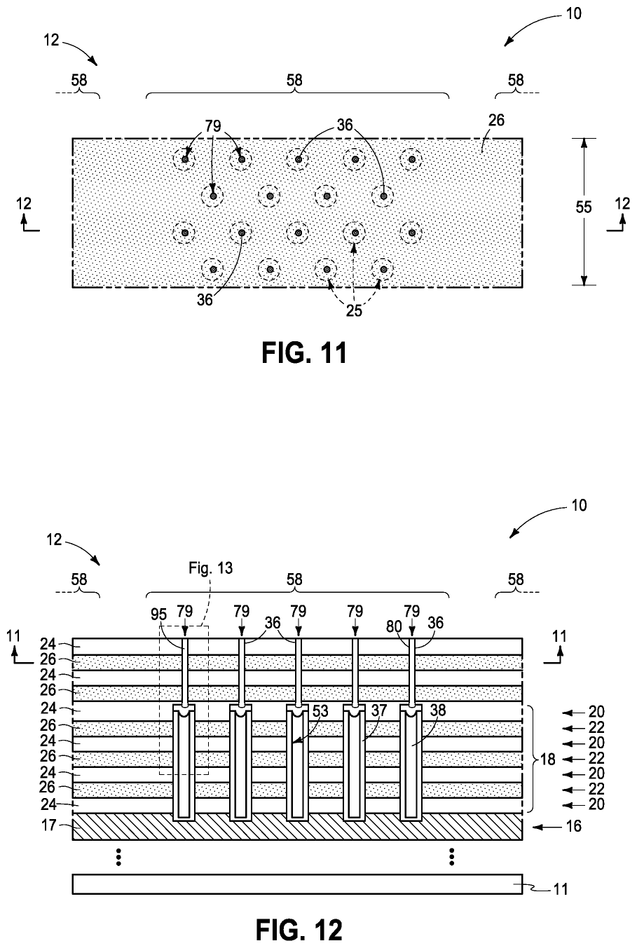

Referring to FIGS. 11-14, upper channel-material strings 83 (e.g., comprising channel material 36) have been formed directly above stack 18 (e.g., in upper channel openings 79), with individual upper channel-material strings 83 being directly above and directly electrically coupled to individual conductive masses 67. Upper channel-material strings 83 will comprise part of select-gate transistors 84 comprising gates 82 (neither of which is shown yet due to the example gate-last processing). An insulator material 95 (e.g., silicon dioxide) may fill remaining volume of upper channel openings 79. A conductive plug (not shown) may be atop or radially inward of and, regardless, directly against upper channel-material string 83 at its top for better electrical connection to other components (not shown) of integrated circuitry above the depicted construction and which are not material to the inventions disclosed herein.

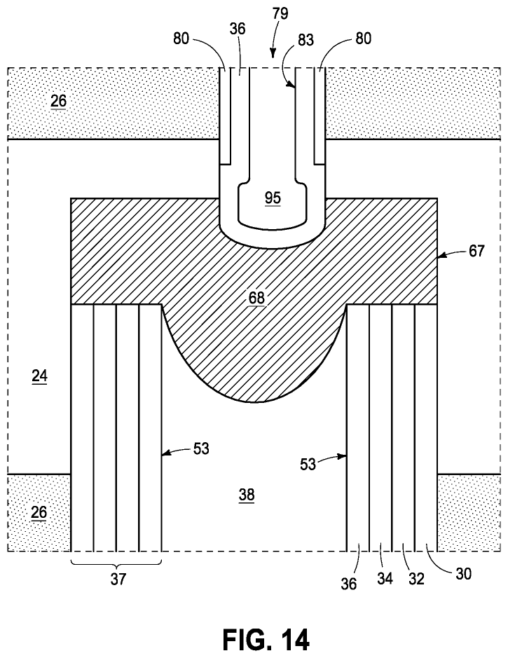

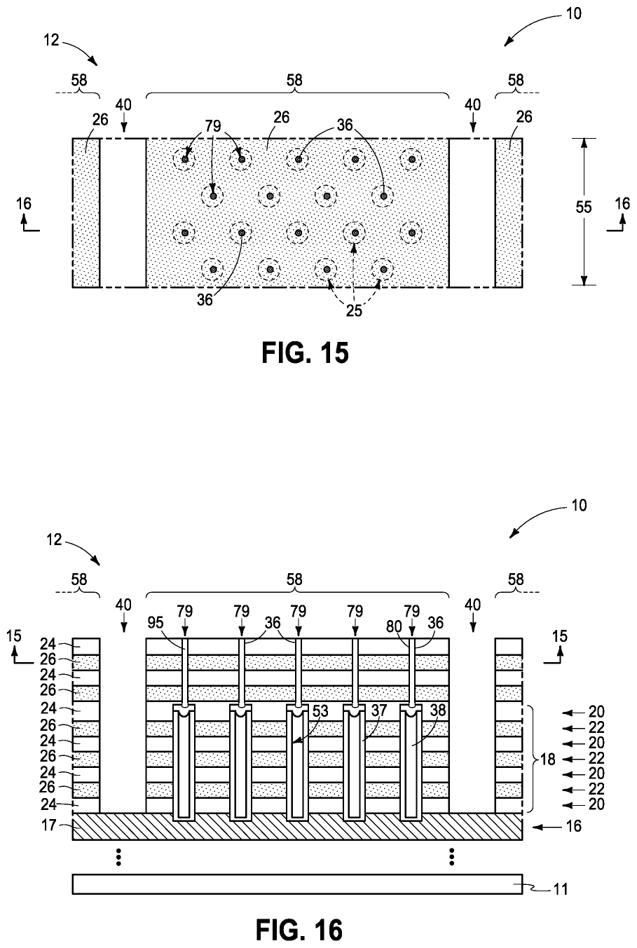

Referring to FIGS. 15 and 16, horizontally-elongated trenches 40 have been formed (e.g., by anisotropic etching) between immediately-laterally-adjacent memory-block regions 58. Trenches 40 will typically be wider than channel openings 25 (e.g., 3 to 10 times wider). Trenches 40 may have respective bottoms that are directly against conductor material 17 (e.g., atop or within) of conductor tier 16 (as shown) or may have respective bottoms that are above conductor material 17 of conductor tier 16 (not shown). Trenches 40 may taper laterally inward and/or outward in vertical cross-section (not shown).

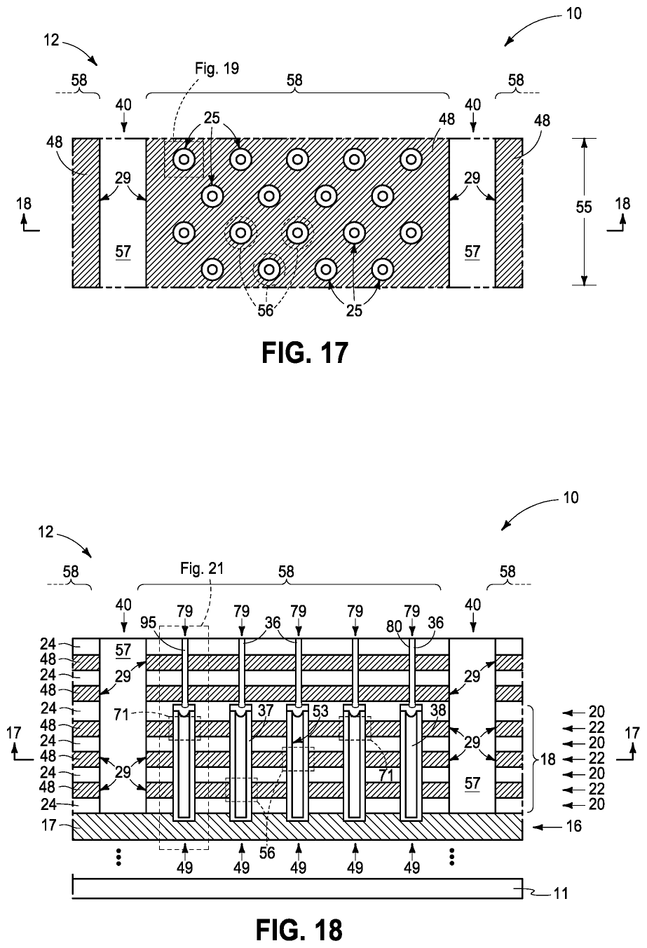

Referring to FIGS. 17-22, material 26 (not shown) of first tiers 22 has been removed, for example by being isotropically etched away through trenches 40 ideally selectively relative to the other exposed materials (e.g., using liquid or vapor H₃PO₄ as a primary etchant where material 26 is silicon nitride and other materials comprise one or more oxides or polysilicon). Material 26 (not shown) in conductive tiers 22 in the example embodiment is sacrificial and has been replaced with conducting material 48, and which has thereafter been removed from trenches 40, thus forming individual conductive lines 29 (e.g., wordlines in stack 18) and elevationally-extending strings 49 of individual transistors and/or memory cells 56 in stack 18.

A thin insulative liner (e.g., Al₂O₃ and not shown) may be formed before forming conducting material 48. Approximate locations of transistors and/or memory cells 56 are indicated with a bracket in some FIGURES and some with dashed outlines in some FIGURES, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conducting material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36. In one embodiment and as shown with respect to the example “gate-last” processing, conducting material 48 of conductive tiers 22 is formed after forming channel openings 25 and/or trenches 40. Alternately, the conducting material of the conductive tiers may be formed before forming channel openings 25 and/or trenches 40 (not shown), for example with respect to “gate-first” processing.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conducting material 48). Regardless, as an additional example, an interface of a storage material and conductive material of a control gate may be sufficient to function as a charge-blocking region in the absence of any separate-composition-insulator material 30. Further, an interface of conducting material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Intervening material 57 has been formed in trenches 40 and thereby laterally-between and longitudinally-along immediately-laterally-adjacent memory blocks 58. Intervening material 57 may provide lateral electrical isolation (insulation) between immediately-laterally-adjacent memory blocks. Such may include one or more of insulative, semiconductive, and conducting materials and, regardless, may facilitate conductive tiers 22 from shorting relative one another in a finished circuitry construction. Example insulative materials are one or more of SiO₂, Si₃N₄, and Al₂O₃. Intervening material 57 may include through array vias (not shown).

Select-gate transistors 84 have been formed and comprise gates 82, and which may be circuit-parallel one another within, for example, a sub-block to function as a single select gate for individual lower channel-material strings 53. In one embodiment and as shown, select-gate transistors 84 are devoid of non-volatile charge-storage regions (e.g., no material 32). In one embodiment and as shown, individual conductive masses 67 comprise an uppermost surface 66 (that may be straight, straight-horizontal, curved, a combination of curved and straight-segments, etc.) that is below a vertically-lowest gate 82 of select-gate transistors 84. In such embodiment, individual upper channel-material strings 83 extend down into one of individual conductive masses 67 to have a bottom 70 therein that is below uppermost surface 66 of the one individual conductive mass 67.

In one embodiment, select-gate transistors 84 are select gate drains and the uppermost first tier 22 in stack 18 below conductive masses 67 comprises a GIDL-generator erase transistor 71 comprising one of lower channel-material strings 53. In one such embodiment, upper channel-material strings 83 above conductive masses 67 are devoid of comprising GIDL-generator erase transistors. In this document, a “GIDL-generator erase transistor” provides GIDL-assisted body biasing during erase, for example as described in Caillat et al., “3DNAND GIDL-Assisted Body Biasing for Erase Enabling CMOS Under Array (CUA) Architecture”, IEEE, 2017, United States, 4 pgs. During erase, such a transistor generates hole current that is largely dominated by a Band-To-Band-Tunneling current (BTBT). Such a transistor has a virtual PN junction, with the P region being created in the transistor body by negative biasing of the gate with respect to the drain. In such architecture, the BTBT current takes place in the virtual PN junction, away from the gate edge, and the BTBT path follows the conduction channel direction. The electric field in the junction is controlled both by the gate to drain potential and the drain to body potential, and so is the transistor GIDL current. During erase, the body potential establishes itself to a value close to an externally applied erase potential (V era). Both the final body potential and its transient evolution are depending on the amount of holes injected, with a larger hole injection leading to an improved body potential of the string (V_{body}) which the GIDL-generator erase transistor 71 may be used to so provide.

Any other attribute(s) or aspect(s) as shown and/or described herein with respect to other embodiments may be used in the embodiments shown and described with reference to the above embodiments.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, a memory array (e.g., 12) comprising strings (e.g., 49) of memory cells (e.g., 56) comprises a stack (e.g., 18) comprising vertically-alternating insulative tiers (e.g., 20) and conductive tiers (e.g., 22). The strings of memory cells comprise lower channel-material strings (e.g., 53) that extend through the insulative tiers and the conductive tiers. Select-gate transistors (e.g., 84) comprising upper channel-material strings (e.g., 83) are directly above the stack. Conductive masses (e.g., 67) are individually vertically-between and directly electrically couple together individual of the upper channel-material strings to individual of the lower channel-material strings. The conductive masses comprise at least one of conductively-doped semiconductive material (e.g., 68) or conductive metal material (e.g., 68). Any other attribute(s) or aspect(s) as shown and/or described herein with respect to other embodiments may be used.

In one embodiment, a memory array (e.g., 12) comprising strings (e.g., 49) of memory cells (e.g., 56) comprises a stack (e.g., 18) comprising vertically-alternating insulative tiers (e.g., 20) and conductive tiers (e.g., 22). The strings of memory cells comprise lower channel-material strings (e.g., 53) that extend through the insulative tiers and the conductive tiers. Select-gate transistors (e.g., 84) comprising upper channel-material strings (e.g., 83) are directly above the stack. Conductive masses (e.g., 67) are individually vertically-between and directly electrically couple together individual of the upper channel-material strings to individual of the lower channel-material strings. Individual of the conductive masses comprise an uppermost surface (e.g., 66) that is below a vertically-lowest gate (e.g., 82) of the select-gate transistors. The individual upper channel-material strings extend down into one of the individual conductive masses to have a bottom (e.g., 70) therein that is below the uppermost surface of the one individual conductive mass. Any other attribute(s) or aspect(s) as shown and/or described herein with respect to other embodiments may be used.

In some prior methods and in accordance with method aspects of the inventions disclosed herein, upper channel-material strings are formed later-in-time compared to formation of the lower channel-material strings, thus leading to more electrically-resistant contact interfaces there-between than is desired. Forming of conductive masses as described herein may reduce such.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the FIGURES or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming a memory array comprising strings of memory cells comprises forming a stack comprising vertically-alternating different-composition first tiers and second tiers. The stack comprises lower channel-material strings extending through the first tiers and the second tiers. Conductive masses are formed that comprise at least one of conductively-doped semiconductive material or conductive metal material. Individual of the conductive masses are atop and directly electrically coupled to individual of the lower channel-material strings. Upper channel-material strings of select-gate transistors are formed directly above the stack. Individual of the upper channel-material strings are directly above and directly electrically coupled to individual of the conductive masses.

In some embodiments, a method used in forming a memory array comprising strings of memory cells comprises forming a stack comprising vertically-alternating different-composition first tiers and second tiers. The stack comprises lower channel-material strings extending through the first tiers and the second tiers. Conductive masses are formed that are individually atop and directly electrically coupled to individual of the lower channel-material strings. Upper channel-material strings of select-gate transistors are formed directly above the stack. Individual of the upper channel-material strings are directly above and directly electrically coupled to individual of the conductive masses. The individual conductive masses comprise an uppermost surface that is below a vertically-lowest gate of the select-gate transistors. The individual upper channel-material strings extend down into one of the individual conductive masses to have a bottom therein that is below the uppermost surface of the one individual conductive mass.

In some embodiments, a memory array comprising strings of memory cells comprises a stack comprising vertically-alternating insulative tiers and conductive tiers. Strings of memory cells comprise lower channel-material strings that extend through the insulative tiers and the conductive tiers. Select-gate transistors comprise upper channel-material strings directly above the stack. Conductive masses are individually vertically-between and directly electrically couple together individual of the upper channel-material strings to individual of the lower channel-material strings. The conductive masses comprise at least one of conductively-doped semiconductive material or conductive metal material.

In some embodiments, a memory array comprising strings of memory cells comprises a stack comprising vertically-alternating insulative tiers and conductive tiers. Strings of memory cells comprise lower channel-material strings that extend through the insulative tiers and the conductive tiers. Select-gate transistors comprise upper channel-material strings directly above the stack. Conductive masses are vertically-between and directly electrically couple together individual of the upper channel-material strings to individual of the lower channel-material strings. Individual of the conductive masses comprise an uppermost surface that is below a vertically-lowest gate of the select-gate transistors. The individual upper channel-material strings extend down into one of the individual conductive masses to have a bottom therein that is below the uppermost surface of the one individual conductive mass.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming a memory array comprising strings of memory cells, comprising:
forming a stack comprising vertically-alternating different-composition first tiers and second tiers, the stack comprising lower channel-material strings extending through the first tiers and the second tiers;
forming conductive masses comprising at least one of conductively-doped semiconductive material or conductive metal material, individual of the conductive masses being atop and directly electrically coupled to individual of the lower channel-material strings; and
forming upper channel-material strings of select-gate transistors directly above the stack, individual of the upper channel-material strings being directly above and directly electrically coupled to individual of the conductive masses.

2. The method of claim 1 wherein the at least one is only one of the conductively-doped semiconductive material and the conductive metal material.

3. The method of claim 1 wherein the at least one is both of the conductively-doped semiconductive material and the conductive metal material.

4. The method of claim 1 wherein the at least one comprises the conductively-doped semiconductive material.

5. The method of claim 4 wherein the conductively-doped semiconductive material comprises conductively n-type doped semiconductive material.

6. The method of claim 5 wherein the conductively-doped semiconductive material comprises conductively n-type doped polysilicon.

7. The method of claim 1 wherein the at least one comprises the conductive metal material.

8. The method of claim 1 wherein the individual conductive masses comprise an uppermost surface that is below a vertically-lowest gate of the select-gate transistors, the individual upper channel-material strings extending down into one of the individual conductive masses to have a bottom therein that is below the uppermost surface of the one individual conductive mass.

9. The method of claim 1 wherein the select-gate transistors are select gate drains, an uppermost first tier in the stack below the conductive masses comprising a GIDL-generator erase transistor comprising one of the lower channel-material strings.

10. The method of claim 9 wherein the upper channel-material strings above the conductive masses are devoid of comprising GIDL-generator erase transistors.

11. A method used in forming a memory array comprising strings of memory cells, comprising:
forming a stack comprising vertically-alternating different-composition first tiers and second tiers, the stack comprising lower channel-material strings extending through the first tiers and the second tiers;
forming conductive masses that are individually atop and directly electrically coupled to individual of the lower channel-material strings; and
forming upper channel-material strings of select-gate transistors directly above the stack, individual of the upper channel-material strings being directly above and directly electrically coupled to individual of the conductive masses, the individual conductive masses comprising an uppermost surface that is below a vertically-lowest gate of the select-gate transistors, the individual upper channel-material strings extending down into one of the individual conductive masses to have a bottom therein that is below the uppermost surface of the one individual conductive mass.

12. The method of claim 11 wherein the select-gate transistors are select gate drains, an uppermost first tier in the stack below the conductive masses comprising a GIDL-generator erase transistor comprising one of the lower channel-material strings.

13. The method of claim 12 wherein the upper channel-material strings above the conductive masses are devoid of comprising GIDL-generator erase transistors.

14. A memory array comprising strings of memory cells, comprising:
a stack comprising vertically-alternating insulative tiers and conductive tiers, strings of memory cells comprising lower channel-material strings that extend through the insulative tiers and the conductive tiers;
select-gate transistors comprising upper channel-material strings directly above the stack; and
conductive masses that are individually vertically-between and directly electrically couple together individual of the upper channel-material strings to individual of the lower channel-material strings, the conductive masses comprising at least one of conductively-doped semiconductive material or conductive metal material.

15. The memory array of claim 14 wherein the at least one is only one of the conductively-doped semiconductive material and the conductive metal material.

16. The memory array of claim 14 wherein the at least one is both of the conductively-doped semiconductive material and the conductive metal material.

17. The memory array of claim 14 wherein the at least one comprises the conductively-doped semiconductive material.

18. The memory array of claim 17 wherein the conductively-doped semiconductive material comprises conductively n-type doped semiconductive material.

19. The memory array of claim 18 wherein the conductively-doped semiconductive material comprises conductively n-type doped polysilicon.

20. The memory array of claim 14 wherein the at least one comprises the conductive metal material.

21. The memory array of claim 14 wherein the individual conductive masses comprise an uppermost surface that is below a vertically-lowest gate of the select-gate transistors, the individual upper channel-material strings extending down into one of the individual conductive masses to have a bottom therein that is below the uppermost surface of the one individual conductive mass.

22. The memory array of claim 14 wherein the select-gate transistors are select gate drains, an uppermost first tier in the stack below the conductive masses comprising a GIDL-generator erase transistor comprising one of the lower channel-material strings.

23. The memory array of claim 22 wherein the upper channel-material strings above the conductive masses are devoid of comprising GIDL-generator erase transistors.

24. A memory array comprising strings of memory cells, comprising:
a stack comprising vertically-alternating insulative tiers and conductive tiers, strings of memory cells comprising lower channel-material strings that extend through the insulative tiers and the conductive tiers;
select-gate transistors comprising upper channel-material strings directly above the stack; and
conductive masses that are vertically-between and directly electrically couple together individual of the upper channel-material strings to individual of the lower channel-material strings, individual of the conductive masses comprising an uppermost surface that is below a vertically-lowest gate of the select-gate transistors, the individual upper channel-material strings extending down into one of the individual conductive masses to have a bottom therein that is below the uppermost surface of the one individual conductive mass.

25. The memory array of claim 24 wherein the select-gate transistors are select gate drains, an uppermost first tier in the stack below the conductive masses comprising a GIDL-generator erase transistor comprising one of the lower channel-material strings.

26. The memory array of claim 25 wherein the upper channel-material strings above the conductive masses are devoid of comprising GIDL-generator erase transistors.
